(19) United States
(12) Patent Application Publication
(10) Pub. No.: US 2014/0001480 A1
(43) Pub. Date: Jan. 2, 2014

(54) Lead Frame Packages and Methods of Formation Thereof

(71) Applicants: Ralf Otremba, Kaufbeuren (DE); Klaus Schiess, Allensbach (DE)

(72) Inventors: Ralf Otremba, Kaufbeuren (DE); Klaus Schiess, Allensbach (DE)

(73) Assignee: INFINEON TECHNOLOGIES AG, Neubiberg (DE)

(21) Appl. No.: 13/540,469

(22) Filed: Jul. 2, 2012

(51) Int. Cl. H01L 23/495; H01L 21/28

(52) U.S. Cl. 257/76; 257/676; 438/122; 257/E23.031; 257/E21.158

(57) ABSTRACT

In accordance with an embodiment of the present invention, a semiconductor device includes a semiconductor chip disposed over a lead frame, and a clip disposed over the semiconductor chip. A major surface of the semiconductor chip includes a contact pad and a control contact pad. The contact pad has a first portion along a first side of the control contact pad and a second portion along an opposite second side of the control contact pad. The clip electrically couples the first portion and the second portion with a first lead of the lead frame. A wire bond electrically couples the control contact pad with a second lead of the lead frame.

### TECHNICAL FIELD

The present invention relates generally to electronic devices, and more particularly to lead frame packages and methods of formation thereof.

### BACKGROUND

Semiconductor devices are used in a variety of electronic and other applications. Semiconductor devices comprise, among other things, integrated circuits or discrete devices that are formed on semiconductor wafers by depositing one or more types of thin films of material over the semiconductor wafers, and patterning the thin films of material to form the integrated circuits.

Lead frame packages are a type of packaging used for packaging semiconductor devices. The semiconductor devices are typically packaged within a ceramic or a plastic body to protect the semiconductor devices from physical damage or corrosion. The packaging also supports the electrical contacts required to connect a semiconductor device, also referred to as a die or a chip, to other devices external to the packaging. Many different types of packaging are available depending on the type of semiconductor device and the intended use of the semiconductor device being packaged. Typical packaging features, such as dimensions of the package, pin count, etc., may comply, among others, with open standards from Joint Electron Devices Engineering Council (JEDEC). Packaging may also be referred as semiconductor device assembly or simply assembly.

### SUMMARY OF THE INVENTION

In accordance with an embodiment of the present invention, a semiconductor device comprises a semiconductor chip disposed over a lead frame, and a clip disposed over the semiconductor chip. A major surface of the semiconductor chip includes a contact pad and a control contact pad. The contact pad has a first portion along a first side of the control contact pad and a second portion along an opposite second side of the control contact pad. The clip electrically couples the first portion and the second portion with a first lead of the lead frame. A wire bond electrically couples the control contact pad with a second lead of the lead frame.

In accordance with an alternative embodiment of the present invention, an electronic device comprises a lead frame having a plurality of leads disposed in a first plane, a semiconductor chip disposed over the lead frame, and a clip disposed over the semiconductor chip. The clip is symmetric along a line on the first plane. The clip electrically couples the semiconductor chip to a first lead of the plurality of leads and a second lead of the plurality of leads. A bond pad is disposed at a third lead of the plurality of leads. A bond wire electrically couples the semiconductor chip to the bond pad.

In accordance with an alternative embodiment of the present invention, a method of forming a semiconductor package comprises locating a semiconductor chip over a lead frame, and attaching a clip over the semiconductor chip. The semiconductor chip has a contact pad and a control contact pad. The contact pad has a first portion along a first side of the control contact pad and a second portion along an opposite second side of the control contact pad. The clip electrically couples the first portion and the second portion with a first lead of the lead frame. The method further includes electrically coupling the control contact pad with a second lead of the lead frame.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1, which includes FIGS. 1A-1C, illustrates a semiconductor package in accordance with an embodiment of the present invention, wherein FIG. 1A illustrates a top view, wherein FIG. 1C illustrates a cross-sectional view, and wherein FIG. 1B illustrates a partial top view;

FIG. 2 illustrates a top view of the semiconductor package in accordance with an alternative embodiment of the present invention;

FIG. 3 illustrates a top view of the semiconductor package in accordance with an alternative embodiment of the present invention;

FIG. 4 illustrates a clip and a semiconductor chip of a semiconductor package in accordance with an alternative embodiment of the present invention;

FIG. 5 which includes FIGS. 5A and 5B, illustrates a semiconductor package having a clip disposed over a plurality of semiconductor chips in accordance with alternative embodiments of the present invention; and

FIGS. 6-13 illustrate a semiconductor device during various stages of fabrication in accordance with an embodiment of the invention.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the present invention provides many applicable inventive concepts that can be embodied in a wide variety of contexts. The embodiments discussed are merely illustrative of a few ways to make and use the invention, and do not limit the scope of the invention.

Power semiconductor devices are one type of semiconductor devices used in many applications. Power semiconductor devices support large currents and may generate large amount of heats. Parasitic resistances of conventional wire bonds can degrade performance of power devices. However, the cost of packaging has to be tightly controlled. As a consequence, improvements in packaging have to be minimize parasitic resistance, improve heat conduction without increasing costs.

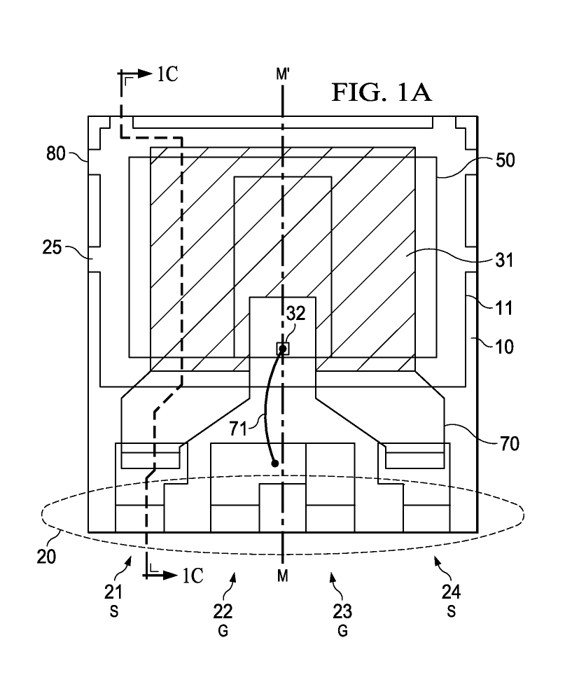

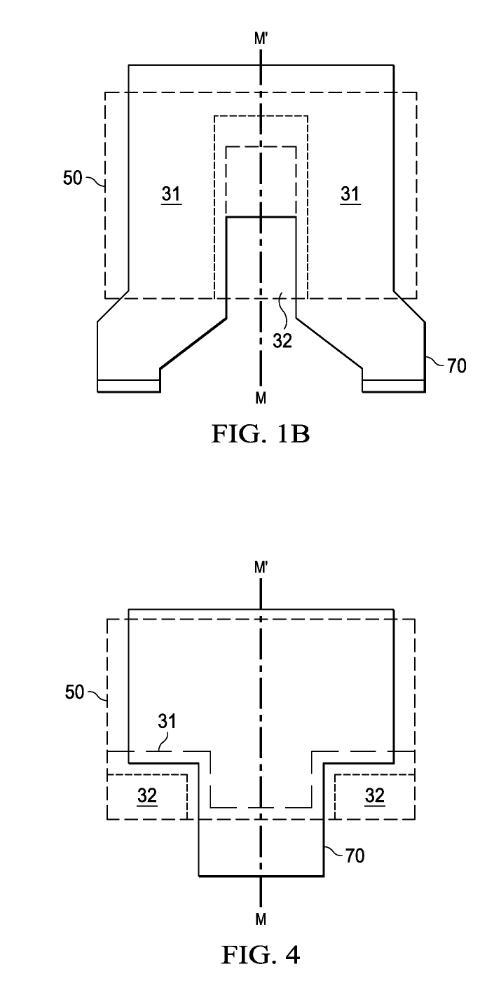

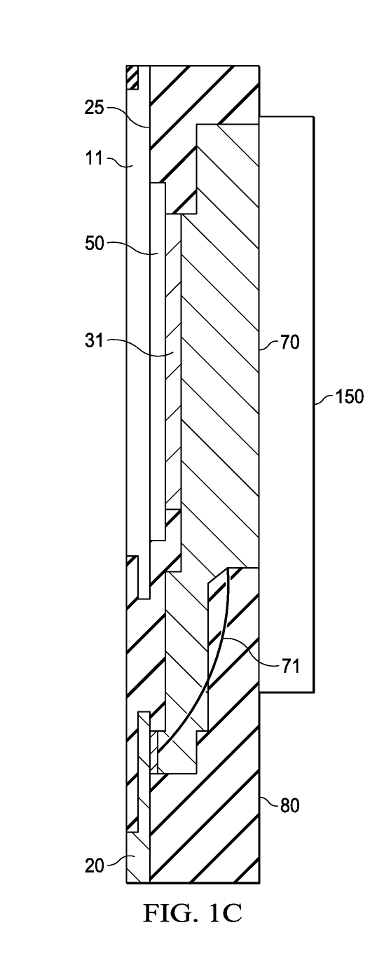

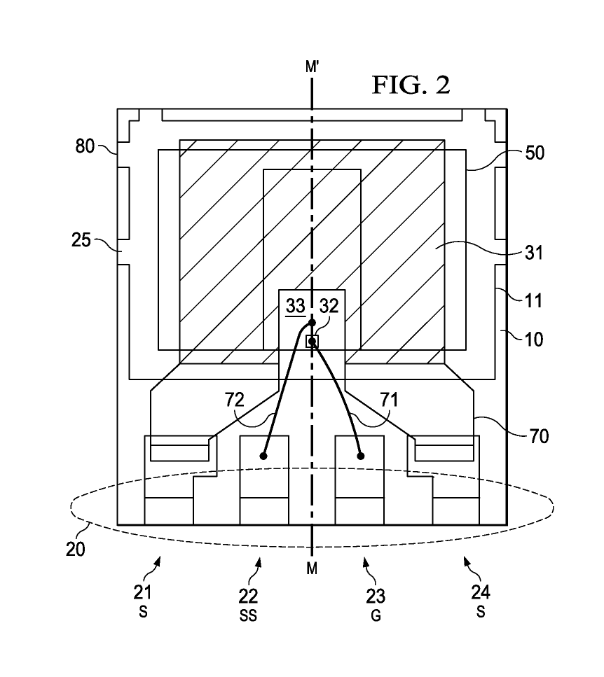

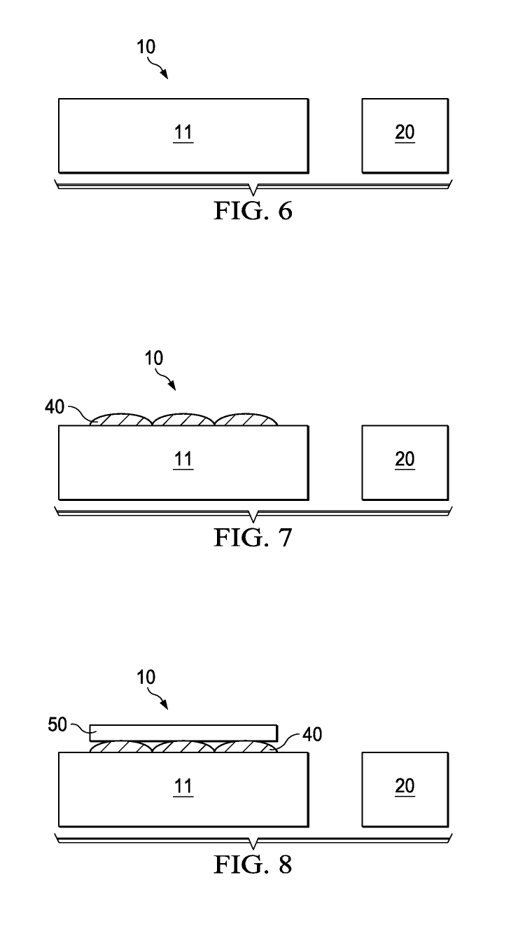

A structural embodiment of the present invention will be described using FIG. 1. Further structural embodiments of the present invention will be described using FIGS. 2-5. Methods of fabricating the semiconductor package will be described using FIGS. 6-13.

FIG. 1, which includes FIGS. 1A-1C, illustrates a semiconductor package in accordance with an embodiment of the present invention, wherein FIG. 1A illustrates a top view, wherein FIG. 1C illustrates a cross-sectional view, and wherein FIG. 1B illustrates a partial top view.

Referring to FIG. 1A, the semiconductor package includes a semiconductor chip 50 disposed over a lead frame 10. The lead frame 10 includes a die paddle 11 (die attach) and a plurality of leads 20. As an illustration, the plurality of leads 20 comprises a first lead 21, a second lead 22, a third lead 23, a fourth lead 24, and a plurality of fifth leads 25.

In various embodiments, the semiconductor chip 50 may comprise a discrete semiconductor device. In further embodiments, the semiconductor chip 50 may comprise a plurality of semiconductor devices as in an integrated circuit.

In one embodiment, the semiconductor chip 50 is a two terminal power device such as a PIN diode or a Schottky diode. In one or more embodiments, the semiconductor chip 50 is a three terminal device such as a power metal insulator semiconductor field effect transistor (MISFET), a junction field effect transistor (JFET), bipolar junction transistor (BJT), an insulated gate bipolar transistor (IGBT), or a thyristor.

A clip 70 is disposed over the semiconductor chip 50 and couples at least one contact pad of the semiconductor chips 50 with at least one of the plurality of leads 20. In one embodiment, the semiconductor chip 50 has a first contact pad 31 and a second contact 32 disposed at the top surface of the semiconductor chip 50. In one embodiment, when the semiconductor chip 50 comprises a transistor, the first contact pad 31 is coupled to a source/emitter region of the transistor. As a consequence, the first contact pad 31 supports much larger currents than the second contact pad 32, which may be coupled to a control region of the semiconductor chip 50. In one embodiment, the semiconductor chip 50 may comprise a discrete vertical transistor having the source/emitter region in one side and a drain/collector region on an opposite side. The fifth lead 25 may be coupled to a drain/collector region of the discrete vertical transistor through the die paddle 11.

FIG. 1B illustrates a partial top view of the clip 70 and the semiconductor chip 50. In one or more embodiments, the first contact pad 31 surrounds the second contact pad 32 as illustrated in FIG. 1B. In various embodiments, the clip 70 which contacts the first contact pad 31 also surrounds the second contact pad 32. In one or more embodiments, the clip 70 may have a symmetrical shape around the second contact pad 32. For example, the clip 70 is symmetric about a mirror axis MM′ in one or more embodiments. The mirror axis MM′ is oriented along a direction parallel to the plurality of leads 20 in one or more embodiments.

In one embodiment, the first lead 21 and the fourth lead 24 are coupled to the first contact pad 31 through the clip 70 while the second lead 22 and the third lead 23 are coupled to the second contact pad 32 through a first wire bond 71 (see also FIG. 1A). Thus, the second lead 22 and the third lead 23 are disposed between the first lead 21 and the fourth lead 24. Consequently, the clip 70 has a symmetric shape, which uniformly removes heat generated from the semiconductor chip 50 during operation. In various embodiments, power semiconductor devices may have as much as 10 W power loss through the device during operation, which may be released as heat. High temperatures generated within the semiconductor chips 50 may result in performance degradation and may even result in permanent failure. Therefore, efficiently removing this generated heat is very critical to the performance of such power devices.

In various embodiments, advantageously, the heat generated at the semiconductor chip 50 is uniformly removed because of the symmetric nature of the clip 70. In contrast, an asymmetrically shaped clip 70 will remove heat asymmetrically, which may result in local hot spots in certain regions of the semiconductor chip 50. Such hot spots can result in device degradation and failure due to a number of reasons. For example, hot spots can generate regions of high stress, which may result in delamination of surrounding layers. Thus, embodiments of the invention avoid hot spots within the semiconductor chip 50 by uniformly removing heat.

In various embodiments, the clip 70 covers or overlaps at least 70% of the surface area of the major surface of the semiconductor chip 50. In one or more embodiments, the clip 70 covers or overlaps 70% to about 100% of the surface area of the major surface of the semiconductor chip 50. In one or more embodiments, the clip 70 covers or overlaps 80% to 90% of the surface area of the major surface of the semiconductor chip 50.

As illustrated, the second lead 22 and the third lead 23 are coupled to the second contact pad 32 through a first wire bond 71 in one embodiment. In one or more embodiments, the second lead 22 and the third lead 23 may be coupled to the second contact pad 32 through separate wire bonds.

FIG. 1C illustrates a cross-sectional view of the semiconductor package along the line 1C of FIG. 1A in accordance with an embodiment of the invention.

As described with respect to FIG. 1A, the semiconductor chip 50 is disposed over the die paddle 11 of the lead frame 10. The clip 70 is disposed over the semiconductor chip 50 and is coupled to the plurality of leads 20 of the lead frame 10. In various embodiments, the clip 70 is at least ten times thicker than the semiconductor chip 50 to enhance heat conduction away from the semiconductor chip 50. In one or more embodiments, the clip 70 is about ten times to about 100 times the thickness of the semiconductor chip 50. In one or more embodiments, the clip 70 is about 20 times to about 50 times the thickness of the semiconductor chip 50. In various embodiments, the clip 70 has a thickness of about 0.1 mm to about 2 mm, and about 0.5 mm in one embodiment. Besides efficiently removing heat, a thicker clip 50 also minimizes parasitic resistance through the clip 50. As illustrated in FIG. 1C, advantageously, in some embodiments, an additional heat sink 150 may be mounted over the clip 70.

In various embodiments, the semiconductor package may be any suitable type of package such as a small-outline integrated circuit package, plastic (dual) small-outline package, thin small-outline package, shrink small-outline package, thin-shrink small-outline package, dual flat no-lead package, quad flat package, quad flat no-lead (QFN) surface mount package including a power QFN package.

FIG. 2 illustrates a top view of the semiconductor package in accordance with an alternative embodiment of the present invention.

This embodiment may include the features described above with respect to FIG. 1. Further, this embodiment may also include a third contact pad 33 (a sense pad, e.g., for sensing the current in the source/emitter region) coupled to the second lead 22 through a second wire bond 72. The third contact pad 33 may be used to sense the source voltage, which may be used to adjust the control voltage. Again, as the third contact pad 33 is used for sensing operations, the current flowing through the second wire bond 72 is not significant and therefore the second wire bond 72 does not introduce a significant resistance.

Unlike the prior embodiment in which the second lead 22 was coupled to the second contact pad 32, which coupled to a gate region, in this embodiment, the second lead 22 is coupled to the third contact pad 33. In alternative embodiments, separate leads of the plurality of leads 20 may be used to contact the third contact pad 33 (sense pad).

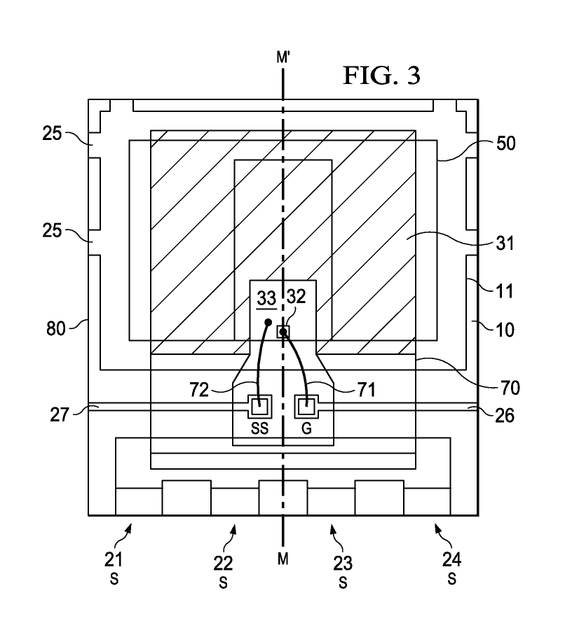

FIG. 3 illustrates a top view of the semiconductor package in accordance with an alternative embodiment of the present invention.

Similar to the embodiment of FIG. 3, this embodiment also illustrates a third contact pad 33 (a sense pad). In this embodiment, the plurality of leads 20 include a first lead 21, a second lead 22, a third lead 23, a fourth lead 24, a plurality of fifth leads 25, a sixth lead 26, and a seventh lead 27. The clip 70 couples the first contact pad 31 with the first lead 21, the second lead 22, the third lead 23, and the fourth lead 24. Although four leads are coupled to the first contact pad 31, in various embodiments, more number of leads may be used.

In this embodiment, the first lead 21, the second lead 22, the third lead 23, and the fourth lead 24 are located on one side of the lead frame 10. The sixth lead 26 is coupled to the second contact pad 32 through a first wire bond 71 (e.g., thereby coupled to a control region) while the seventh lead 27 is coupled to the third contact pad 33 via a second wire bond 72 (e.g., thereby coupled to a sense region). This embodiment helps to minimize the length of the wire bonds because the sixth lead 26 and the seventh lead 27 may be placed closer to the die attach 11.

FIG. 4 illustrates a clip and a semiconductor chip of a semiconductor package in accordance with an alternative embodiment of the present invention.

In this embodiment, the source/emitter region is disposed between the control regions. Therefore, the first contact pad 31 is disposed between adjacent second contact pads 32. The clip 70 may be formed over the semiconductor chip 50 having a symmetric shape as described previously.

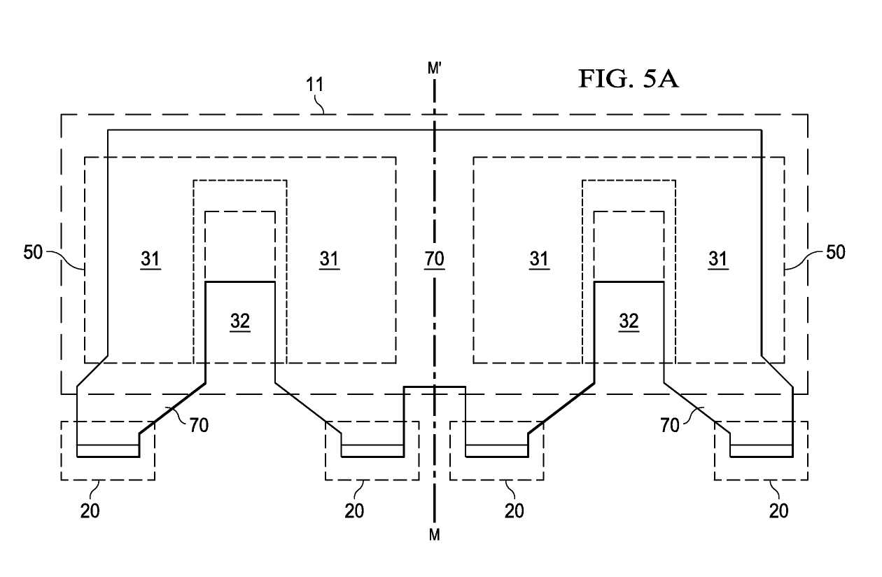

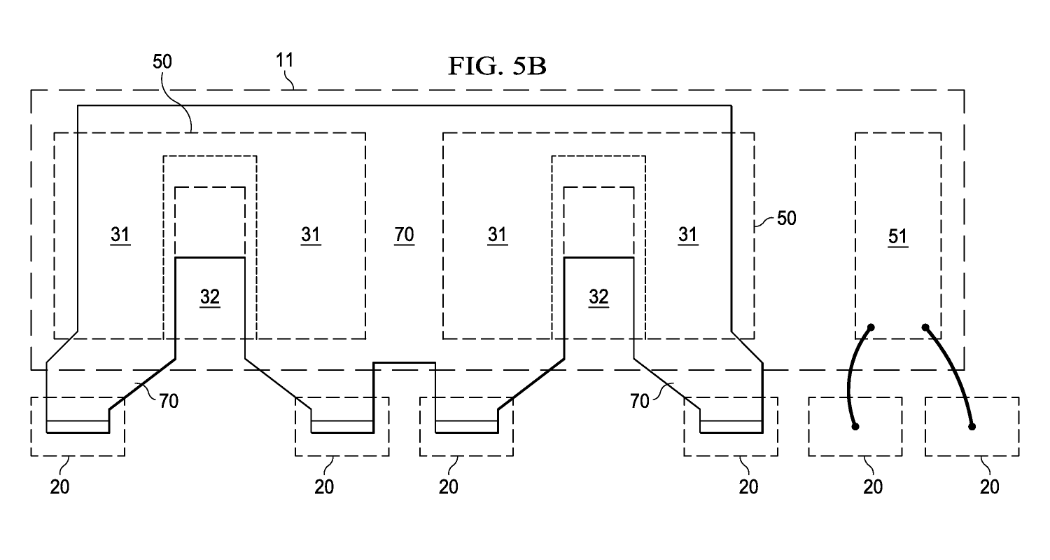

FIG. 5, which includes FIGS. 5A and 5B, illustrates a semiconductor package having a clip disposed over a plurality of semiconductor chips in accordance with alternative embodiments of the present invention.

Unlike the prior embodiments, in some embodiments as described herein, a plurality of the semiconductor chips 50 may be placed over the die attach 11 of a lead frame 10. For example, in one embodiment, the plurality of semiconductor chips 50 may be connected in parallel. Therefore, a common clip 70 may be formed over the plurality of semiconductor chips 50 and may be coupled to a plurality of leads 20. The clip 70 may be coupled to the source/emitter regions of the plurality of semiconductor chips 50 while the drain/collector regions of the plurality of semiconductor chips 50 may be coupled to the plurality of leads 20 through the die attach 11 of the lead frame as described in prior embodiments. Various embodiments of the present invention include more than two semiconductor chips although only two semiconductor chips are illustrated in FIG. 5A.

Further, as illustrated in FIG. 5B, in alternative embodiments, additional functional circuitry such as a functional chip 51, which may be a logic, analog, memory, or mixed signal chip, may be placed over the die paddle 11. The functional chip 51 may be coupled to the plurality of leads 20 of the lead frame 10 through suitable interconnects, which may be wire bonds in one embodiment.

FIGS. 6-13 illustrate a semiconductor device during various stages of fabrication in accordance with an embodiment of the invention.

FIG. 6 illustrates a lead frame 10 used in packaging the semiconductor device in accordance with embodiments of the invention. The lead frame 10 may comprise any type of suitable structure, for example, arrangement of the plurality of leads 20 around the die paddle 11.

In various embodiments, the lead frame 10 may be any type of package. In one or more embodiments, the lead frame 10 may be a small outline (SO) package such as SuperSO, power SO-8 type of package, transistor outline package such as TO220, as well as other types of lead frame selected based on the package type.

Referring to FIG. 7, a plurality of solder balls 40 are applied over the lead frame 10. In alternative embodiments, an adhesive layer may be applied over the lead frame 10. In one or more embodiments, a conductive paste may be applied over the lead frame 10. In another embodiment, the adhesive layer may comprise a nano-conductive paste.

As next illustrated in FIG. 8, a semiconductor chip 50 is placed over the plurality of solder balls 40. In various embodiments, the semiconductor chip 50 may comprise a power semiconductor device, which may be a discrete device in one embodiment. In one embodiment, the semiconductor chip 50 is a two terminal device such as a PIN diode or a Schottky diode. In one or more embodiments, the semiconductor chip 50 is a three terminal device such as a power metal insulator semiconductor field effect transistor (MISFET), a junction field effect transistor (JFET), bipolar junction transistor (BJT), an insulated gate bipolar transistor (IGBT), or a thyristor.

The semiconductor chip 50 may be formed using conventional processing, for example, within a wafer, which is diced to form the plurality of the semiconductor chip 50. As described above, the semiconductor chip 50 may be formed on a silicon substrate such as a bulk silicon substrate or a silicon on insulator (SOI) substrate. Alternatively, the semiconductor chip 50 may be a device formed on silicon carbide (SiC). Embodiments of the invention may also include devices formed on compound semiconductor substrates and may include devices on hetero-epitaxial substrates. In one embodiment, the semiconductor chip 50 is a device formed at least partially on gallium nitride (GaN), which may be a GaN on sapphire or silicon substrate.

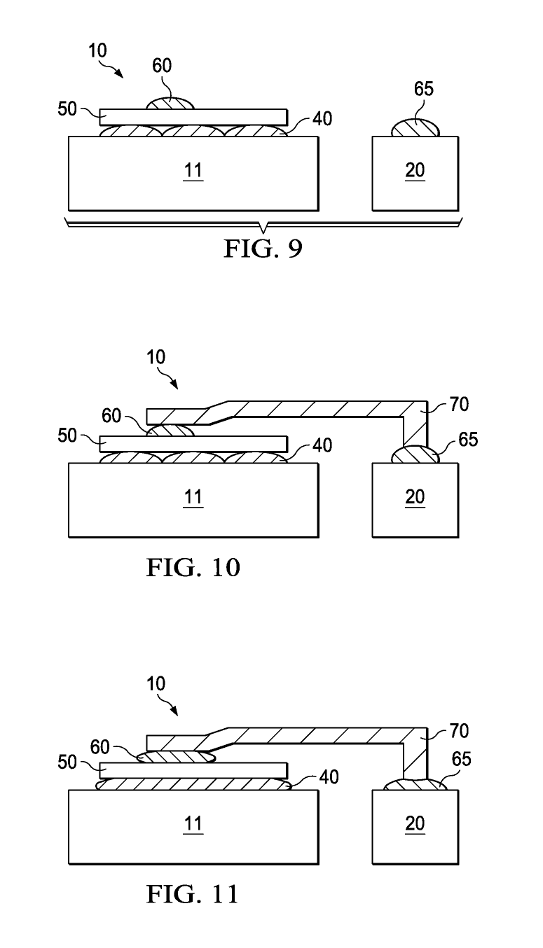

Referring to FIG. 9, a chip adhesive layer 60 and a lead adhesive layer 65 are formed. The chip adhesive layer 60 and the lead adhesive layer 65 may be formed using a common process and may comprise a soldering material in various embodiments. In alternative embodiments, the chip adhesive layer 60 and the lead adhesive layer 65 may comprise other adhesive materials such as conductive pastes, and others.

In various embodiments, the chip adhesive layer 60 and the lead adhesive layer 65 comprise a solder material such as a lead-tin material. In various embodiments, the chip adhesive layer 60 and the lead adhesive layer 65 may comprise any suitable conductive adhesive material including metals or metal alloys such as aluminum, titanium, gold, silver, copper, palladium, platinum, nickel, chromium, nickel-vanadium, and combinations thereof.

The chip adhesive layer 60 and the lead adhesive layer 65 may be formed using deposition processes such as vapor deposition, electroless plating, and electroplating in various embodiments. The chip adhesive layer 60 and the lead adhesive layer 65 may be a single layer or comprise multiple layers with different compositions. For example, in one embodiment, the The chip adhesive layer 60 and the lead adhesive layer 65 may comprise a lead (Pb) layer followed by a tin (Sn) layer. In another embodiment, a SnAg may be deposited as the solder material. Other examples include SnPbAg, SnPb, PbAg, PbIn, and lead free materials such as SnBi, SnAgCu, SnTn, and SiZn. In various embodiments, other suitable materials may be deposited.

A clip 70 is positioned over the chip adhesive layer 60 and the lead adhesive layer 65 as illustrated in FIG. 10. The clip 70 may have a symmetric shape as described in various embodiments of the present invention. In various embodiments, the clip 70 comprises copper. In alternative embodiments, the clip 70 comprises aluminum. In one or more embodiments, the clip comprises a conductive material such as silver, nickel, platinum, gold, graphene, and others. In various embodiments, the clip 70 may have a thickness of about 0.1 mm to about 2 mm.

Referring to FIG. 11, the chip adhesive layer 60 and the lead adhesive layer 65 are subjected to a bonding process.

In various embodiments, the bonding process may cure the adhesive material. In various embodiments, the bonding process may be formed using thermosonic bonding, ultrasonic bonding, or thermo-compression bonding. Thermosonic bonding may utilize temperature, ultrasonic, and low impact force. Ultrasonic bonding may utilize ultrasonic and low impact force. Thermo-compression bonding may utilize temperature and high impact force.

For example, in one case, thermosonic bonding may be used with the clip 70 comprising copper. Bonding temperature, ultrasonic energy, and bond force and time may have to be closely controlled to form a reliable connection from the semiconductor chip 50 to the lead frame 10.

In various embodiments, the bonding process may be performed using a thermal process. In one or more embodiments, the thermal process may be a global thermal process in which the lead frame 10, the semiconductor chip 50, and the clip 70 are placed inside an annealing tool. In an alternative embodiment, the thermal process may be a local thermal process in which localized heating is used to heat the chip adhesive layer 60 and the lead adhesive layer 65. A local thermal process may be performed by using a directed heat source or a directed (electro-magnetic) radiation source.

In one embodiment, a thermal treatment may be performed to form solder balls as illustrated in FIG. 11. In case the chip adhesive layer 60 and the lead adhesive layer 65 comprise a solder material, the thermal treatment reflows the solder material. For example, in the embodiment when chip adhesive layer 60 and the lead adhesive layer 65 comprise a Pb/Sb layer, after reflow high lead alloys including 95 Pb/5 Sn (95/5) or 90 Pb/10 Sn (95/10) with melting temperatures in excess of 300° C. may be formed. Such high melting Pb/Sn alloys are reliable metallurgies which are resistant to material fatigue. In a different embodiment, eutectic 63 Pb/37 Sn (63/37) with a melting temperature of 183° C. may be formed. Similarly, in some embodiments, lead free chip adhesive layer 60 and the lead adhesive layer 65 may be formed having a composition of 97.5 Sn/2.6 Ag (97.5/2.5).

In one or more embodiments, the bonding of the chip adhesive layer 60 and the lead adhesive layer 65 is performed at a temperature between about 100° C. to about 300° C. In one or more embodiments, the chip solder layer 60 and the lead solder layer 65 are heated to less than 350° C. In one or more embodiments, if the chip adhesive layer 60 and the lead adhesive layer 65 comprise a polymer, the bonding temperature may be about 125° C. to about 200° C. Alternatively, in one or more embodiments, if the chip adhesive layer 60 and the lead adhesive layer 65 comprise a solder material, the bonding temperature may be about 250° C. to about 350° C.

Thus, after the heat treatment, the clip 70 is electrically coupled and physically attached to the semiconductor chip 50 using the chip adhesive layer 60 and the lead adhesive layer 65.

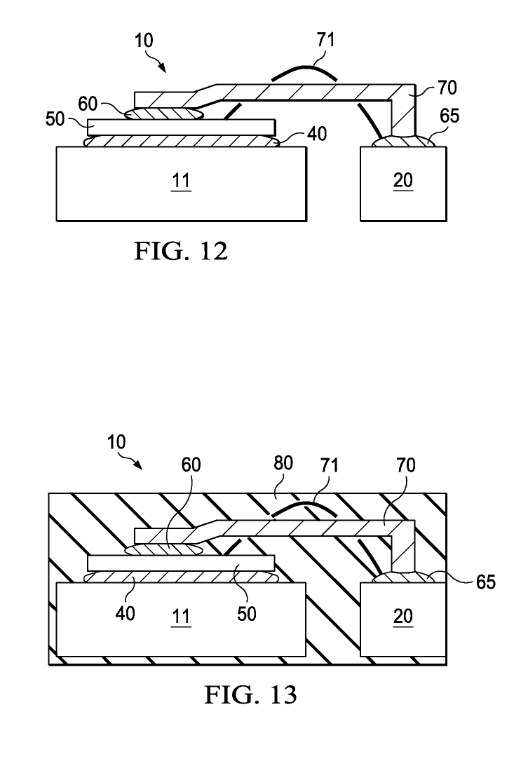

Referring to FIG. 12, a wire bonding process is performed to couple the remaining contact pads to the plurality of leads 20 of the lead frame 10. The wire bonding process may be performed after attaching the clip 70 in some embodiments as the attachment of the clip 70 may require a larger thermal budget process. The wire bonding process may be used to couple the control pads and/or sense pads of the transistor with the plurality of leads 20. The current passing through the control and/or sense pads of the transistor may be much smaller than the current passing through the source pads. Therefore, the control and/or sense pads may be coupled using wire bonds in various embodiments.

In one or more embodiments, the wire bonds (e.g., first wire bond 71) may comprise copper, aluminum, and/or gold wires. The thickness of such aluminum wires may be about 10 μm to about 1000 μm in one or more embodiments. In another embodiment, the wire bonds 330 may comprise gold. The thickness of such gold wires may be about 10 μm to about 100 μm.

In one or more embodiments, high-speed wire bond equipment may be used to minimize the time of forming the wire bonds. Image recognition systems may be used to orient the semiconductor chip 50 during the wire bonding process in some embodiments.

In various embodiments, ball bonding or wedge bonding may be used to attach the wire bonds. In various embodiments, the wire bonds may be formed using thermosonic bonding, ultrasonic bonding, or thermo-compression bonding. Two wire bonds are formed for each interconnection, one at the contact pads (e.g. control contact pad 32 of FIG. 1A) of the semiconductor chip 50 and another at a lead of the plurality of the leads 20 of the lead frame 10. Again, bonding temperature, ultrasonic energy, and bond force and time may be closely controlled to form a reliable connection from the semiconductor chip 50 to the lead frame 10.

In one or more embodiments, a solder flux and a solder material may be deposited for the wire bonding process. The solder material may be a single layer or comprise multiple layers with different compositions. For example, in one embodiment, the solder material may comprises a lead (Pb) layer followed by a tin (Sn) layer. In another embodiment, a SnAg may be deposited as the solder material. Other examples include SnPbAg, SnPb, PbAg, PbIn, and lead free materials such as SnBi, SnAgCu, SnTn, and SiZn. In various embodiments, other suitable materials may be deposited.

Referring next to FIG. 13, an encapsulant 80 is formed around the lead frame 10, the semiconductor chip 50, and the clip 70 sealing the various exposed surfaces. In one or more embodiments, the encapsulant 80 may be applied using a compression molding process. In compression molding, the encapsulant 80 may be placed into a molding cavity, then the molding cavity is closed to compress the encapsulant 80. Compression molding may be used when a single pattern is being molded. In an alternative embodiment, the encapsulant 80 may be applied using a transfer molding process when a plurality of packages is formed together. In other embodiments, the encapsulant 80 may be applied using injection molding, granulate molding, powder molding, or liquid molding. Alternatively, the encapsulant 80 may be applied using printing processes such as stencil or screen printing. A curing process may be performed to form a lead package.

In various embodiments, the encapsulant 80 comprises a dielectric material and may comprise a mold compound in one embodiment. In other embodiments, the encapsulant 80 may comprise one or more of a polymer, a copolymer, a biopolymer, a fiber impregnated polymer (e.g., carbon or glass fibers in a resin), a particle filled polymer, and other organic materials. In one or more embodiments, the encapsulant 80 comprises a sealant not formed using a mold compound, and materials such as epoxy resins and/or silicones. In various embodiments, the encapsulant 80 may be made of any appropriate duroplastic, thermoplastic, a thermosetting material, or a laminate. The material of the encapsulant 80 may include filler materials in some embodiments. In one embodiment, the encapsulant 80 may comprise epoxy material and a fill material comprising small particles of glass or other electrically insulating mineral filler materials like alumina or organic fill materials. The encapsulant 80 may be cured, i.e., subjected to a thermal process to harden thus forming a hermetic seal protecting the semiconductor chip 50. The curing process hardens the encapsulant 80 thereby forming a single substrate holding the semiconductor chip 50.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIGS. 1-13 may be combined with each other in various embodiments. It is therefore intended that the appended claims encompass any such modifications or embodiments.

Although the present invention and its advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor chip disposed over a lead frame, wherein a major surface of the semiconductor chip includes a contact pad and a control contact pad, wherein the contact pad has a first portion along a first side of the control contact pad and a second portion along an opposite second side of the control contact pad;
a clip disposed over the semiconductor chip, wherein the clip electrically couples the first portion and the second portion with a first lead of the lead frame; and
a wire bond electrically coupling the control contact pad with a second lead of the lead frame.

2. The semiconductor device according to claim 1, wherein the clip is disposed symmetrically with respect to the control contact pad.

3. The semiconductor device according to claim 1, wherein the clip electrically couples the first portion and the second portion with a third lead of the lead frame.

4. The semiconductor device according to claim 3, wherein the second lead is disposed between the first lead and the third lead.

5. The semiconductor device according to claim 1, wherein the second lead is oriented in a direction perpendicular to the first lead.

6. The semiconductor device according to claim 1, wherein the clip comprises copper.

7. The semiconductor device according to claim 1, wherein the clip overlaps with at least 70% of the major surface of the semiconductor chip.

8. The semiconductor device according to claim 1, wherein the clip has a thickness of at least 0.1 mm.

9. The semiconductor device according to claim 1, wherein the semiconductor chip comprises a sense contact pad, and wherein the sense contact pad is electrically coupled to a fourth lead of the lead frame through another wire bond.

10. The semiconductor device according to claim 9, wherein the fourth lead is oriented in a direction perpendicular to the first lead.

11. The semiconductor device according to claim 1, wherein the semiconductor chip is a discrete power transistor, wherein the contact pad is electrically coupled to a source/drain region of the discrete power transistor, and wherein the control contact pad is electrically coupled to a control region of the discrete power transistor.

12. The semiconductor device according to claim 11, wherein the discrete power transistor is a silicon based transistor.

13. The semiconductor device according to claim 11, wherein the discrete power transistor is a gallium nitride based transistor.

14. The semiconductor device according to claim 1, further comprising another semiconductor chip disposed over the lead frame, the another semiconductor chip electrically coupled to a third lead of the lead frame through the clip.

15. An electronic device comprising:
a lead frame having a plurality of leads disposed in a first plane;
a semiconductor chip disposed over the lead frame;
a clip disposed over the semiconductor chip, the clip being symmetric along a line on the first plane, the clip electrically coupling the semiconductor chip to a first lead of the plurality of leads and a second lead of the plurality of leads;
a bond pad disposed at a third lead of the plurality of leads; and
a bond wire electrically coupling the semiconductor chip to the bond pad.

16. The electronic device according to claim 15, wherein the line on the first plane is parallel to the first lead.

17. The electronic device according to claim 15, wherein the semiconductor chip has a first contact pad and a control contact pad, wherein the first contact pad has a first portion along a first side of the control contact pad and a second portion along an opposite second side of the control contact pad, and wherein the clip electrically couples the first contact pad with the first lead and the second lead.

18. The electronic device according to claim 17, wherein the clip is disposed symmetrically with respect to the control contact pad.

19. The electronic device according to claim 17, wherein the clip electrically couples the first portion with the first lead and the second portion with the second lead.

20. The electronic device according to claim 19, wherein the second lead is disposed between the first lead and the third lead.

21. The electronic device according to claim 15, wherein the semiconductor chip has a contact pad, a first control contact pad, and a second control contact pad, wherein the contact pad is disposed between the first control contact pad and the second control contact pad, and wherein the clip electrically couples the contact pad with the first lead and the second lead.

22. The electronic device according to claim 15, wherein the second lead is oriented in a direction perpendicular to the first lead.

23. The electronic device according to claim 15, wherein the clip comprises copper.

24. A method of forming a semiconductor package, the method comprising:
locating a semiconductor chip over a lead frame, the semiconductor chip having a contact pad and a control contact pad, the contact pad having a first portion along a first side of the control contact pad and a second portion along an opposite second side of the control contact pad;
attaching a clip over the semiconductor chip, the clip electrically coupling the first portion and the second portion with a first lead of the lead frame; and
electrically coupling the control contact pad with a second lead of the lead frame.

25. The method according to claim 24, wherein the clip is symmetrical with respect to the control contact pad.

26. The method according to claim 24, wherein attaching the clip over the semiconductor chip comprises soldering the clip to the semiconductor chip.

27. The method according to claim 24, wherein electrically coupling the control contact pad with the second lead comprises forming a wire bond using a wire bonding process.

28. The method according to claim 24, further comprising attaching a heat sink to a surface of the semiconductor package proximate the clip.

29. The method according to claim 24, wherein the control contact pad is electrically coupled with the second lead after attaching the clip.
